(19) United States
(12) Patent Application Publication
(10) Pub. No.: US 2013/0207730 A1
(43) Pub. Date: Aug. 15, 2013

(54) IMPEDANCE MATCHING CIRCUIT, POWER AMPLIFIER AND MANUFACTURING METHOD FOR VARIABLE CAPACITOR

(71) Applicant: Electronics and Telecommunications Research Institute, (US)

(72) Inventors: Jongmin LEE, Daejeon (KR); Byoung-Gue Min, Daejeon (KR); Seong-Il Kim, Daejeon (KR); Hyung Sup Yoon, Daejeon (KR); Jae Kyoung Mun, Daejeon (KR); Eun Soo Nam, Daejeon (KR)

(73) Assignee: Electronics and Telecommunications Research Institute, Daejeon (KR)

(21) Appl. No.: 13/743,667

(22) Filed: Jan. 17, 2013

(30) Foreign Application Priority Data
Feb. 15, 2012 (KR) 10-2012-15292

(51) Int. Cl. H03H 7/38; H01G 7/00; H03F 3/21

(52) U.S. Cl. CPC H03H 7/38; H03F 3/21; H01G 7/00
USPC 330/296; 333/32; 330/250; 29/25.41

(57) ABSTRACT

Disclosed is an impedance matching circuit capable of wideband matching. The impedance matching circuit includes: a first variable inductor unit of which one end is connected to the first node and an inductance value varies; a second inductor unit connected between the first node and a second node and having a variable inductance value; a first variable capacitor unit of which one end is connected to the first node and a capacitance value varies; and a second variable capacitor unit of which one end is connected to the second node and a capacitance value varies, and the other end of the first variable capacitor unit and the other end of the second variable capacitor unit are connected to a ground voltage terminal to perform the impedance matching between a circuit connected to the other end of the first variable inductor unit and a circuit connected to the second node.

### CROSS-REFERENCE TO RELATED APPLICATIONS

This application is based on and claims priority from Korean Patent Application No. 10-2012-0015292, filed on Feb. 15, 2012, with the Korean Intellectual Property Office, the disclosure of which is incorporated herein in its entirety by reference.

### TECHNICAL FIELD

The present disclosure relates to an impedance matching circuit capable of wideband matching, which includes a passive element capable of controlling a matching characteristic, a power amplifier circuit including the same, and a manufacturing method for a variable capacitor included in the impedance matching circuit.

### BACKGROUND

With the development of various types of wireless communication technologies, the necessity that wireless terminal and system need to support several wireless communication standards has bee increased. Portable terminals and systems capable of meeting various requirements are required to be developed in order for the wireless terminal and system to support several wireless communication standards. In the wireless communication system, an essential element that occupies the most important position is a power amplifier, and as a result, power amplifiers that are suitable for frequencies used in several services are required in order to satisfy various communication systems.

In the related art, a heterojunction bipolar transistor primarily formed on a GaAs substrate has been used as a power element by considering price, productivity and frequency characteristics, and a monolithic microwave integrated circuit (MMIC) type power amplifier including a bias circuit and a matching circuit suitable for a used frequency has been designed, manufactured and used. The power amplifier using a GaAs based compound, which is manufactured as above is impedance-matched for each frequency which can be used in frequencies required in the wireless communication terminal and system.

Therefore, the power amplifier impedance-matched for each frequency band needs to be provided in order to manufacture the wireless communication terminals and systems which can be used in various frequencies. That is, the wireless communication terminals and systems which can be used in various frequencies need a plurality of power amplifiers impedance-matched for each frequency band, a plurality of switches that enables the power amplifier which is appropriate in each frequency band to be used in the wireless communication terminal and system, and a control circuit for controlling the switches.

In recent years, a study for decreasing the number of the power elements in order to decrease an area occupied by the power amplifier in the total area of the wireless communication terminal dimension and decrease the cost of production has been in progress. To this end, one power amplifier should be used in two or more frequency bands. A tunable matching circuit or a reconfigurable matching circuit that enables the power amplifier to be impedance-matched in a desired frequency is required so that one power amplifier is used in two or more frequency bands.

Another method includes a method that enables the power amplifier and the matching circuit to be operated in a wide frequency band. That is, the method is used to cover various wireless communication systems with one power amplifier by designing the power element and the matching circuit to have a wide bandwidth in the range of 500 MHz to 1 GHz. This method is ideally used to minimize the area of the power amplifier, but it is difficult to cover a total frequency band used in the wireless communication system with one power amplifier with the recent development of information and communication technologies and continuous extension of the frequency band used in the wireless communication system.

FIG. 1 is a configuration diagram of a power amplifier in the related art.

As illustrated in FIG. 1, the power amplifier includes a power amplifying unit illustrated as AMP and an output impedance matching circuit illustrated as M0.

The output impedance matching circuit M0 includes an inductor unit illustrated as L connected between an output terminal of the power amplifying unit AMP and an output node illustrated as OUT, and a capacitor unit illustrated as C connected between the output node OUT and a ground voltage terminal. Herein, an inductance value of the inductor unit L and a capacitance value of the capacitor unit C have fixed values to be impedance-matched with a load illustrated as RL at the frequency used in the wireless communication system where the power amplifier is used.

In the power amplifier of FIG. 1, a power amplifier chip manufactured by a compound semiconductor process is packaged and matched to a board such as a PCB substrate and the like by using a surface mount (SMT) type passive element. As illustrated in FIG. 1, when each one of the inductor unit L and the capacitor unit C (lumped element) having the fixed values is impedance-matched, the maximum output can be transferred to a load illustrated as RL having a predetermined resistance value (for example, 50Ω) only in one predetermined frequency band.

That is, the power amplifier of FIG. 1 cannot satisfy a frequency operating condition for operating in various wireless communication systems as described above.

### SUMMARY

The present disclosure has been made in an effort to provide an impedance matching circuit that further extends a frequency range to enable impedance-matching by controlling capacitance values of one or more capacitors and inductance values of one or more inductors while enabling wideband matching, when the impedance matching circuit includes one or more capacitors and one or more inductors connected to one or more nodes to be configured in multiple stages.

The present disclosure also has been made in an effort to provide a manufacturing method for a variable capacitor that is included in the impedance matching circuit to arbitrarily control the capacitance value according to a bias voltage while decreasing an area thereof with a fixed capacitor.

An exemplary embodiment of the present disclosure provides an impedance matching circuit including: a first variable inductor unit of which one end is connected to the first node and an inductance value varies; a second inductor unit connected between the first node and a second node and having a variable inductance value; a first variable capacitor unit of which one end is connected to the first node and a capacitance value varies; and a second variable capacitor unit of which one end is connected to the second node and a capacitance value varies, and the other end of the first variable capacitor unit and the other end of the second variable capacitor unit are connected to a ground voltage terminal to perform the impedance matching between a circuit connected to the other end of the first variable inductor unit and a circuit connected to the second node.

Another exemplary embodiment of the present disclosure provides a power amplifier circuit including: a power amplifying unit; an output impedance matching unit of which one end is connected to an output node connected with a load to perform impedance matching; and an internal impedance matching unit including a first node connected with an output terminal of the power amplifying unit and a second node connected with the other end of the output impedance matching unit, and performing the impedance matching, and an impedance of the internal impedance matching unit varies.

Yet another exemplary embodiment of the present disclosure provides a manufacturing method for a variable capacitor, including: forming a first element of which a capacitance value depends on a voltage applied to both terminals of a first area on a substrate; forming a second element having a capacitance value fixed to a second area on the substrate adjacent to the first area; and forming metallic wires for connecting the first element and the second element and connecting the first element and the second element with the outside.

According to exemplary embodiments of the present disclosure, it is possible to perform wideband matching by changing a characteristic value of a passive element included in an impedance matching circuit configured in multiple stages.

It is also possible to reduce an area of a variable capacitor with a fixed capacitor while a capacitance value can be arbitrarily controlled according to biasing.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a configuration diagram of a power amplifier in the related art.

FIG. 2 is a configuration diagram of a power amplifier according to an exemplary embodiment of the present disclosure.

FIG. 3 is a configuration diagram of variable capacitor units C1 and C2.

FIGS. 4A to 4K are diagrams for describing a manufacturing method for the variable capacitors C1 and C2 of FIG. 3.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

Hereinafter, matching is a meaning that includes impedance matching.

FIG. 2 is a configuration diagram of a power amplifier according to an exemplary embodiment of the present disclosure.

As illustrated in FIG. 2, the power amplifier includes a power amplifying unit illustrated as AMP, an output impedance matching unit illustrated as M0 of which one end is connected to an output node illustrated as OUT connected with a load RL and which performs impedance matching, a first node illustrated as N1 connected with an output terminal of the power amplifying unit AMP, and a second node illustrated as N2 connected with the other end of the output impedance matching unit M0, and further includes an internal impedance matching unit illustrated as MI performing the impedance matching and an impedance of the internal impedance matching unit MI is variable.

Hereinafter, the power amplifier will be described with reference to FIG. 2.

The power amplifying unit AMP is a kind of amplifier that amplifies and outputs an input signal (not illustrated in FIG. 2). The power amplifying unit AMP amplifies the input signal to output an amplified signal which may be used as power in a system including itself. The power amplifying unit AMP may be manufactured by packaging a power amplifier chip manufactured by a compound semiconductor process.

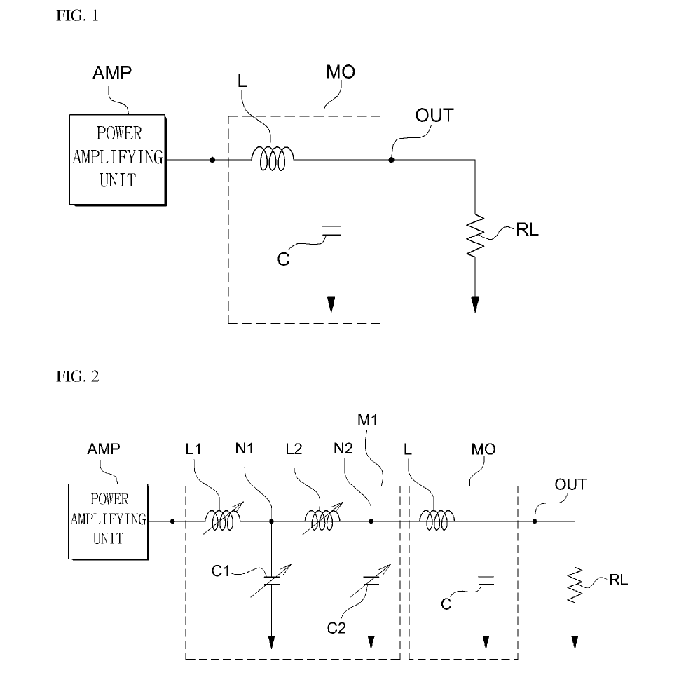

The internal impedance matching unit MI and the external impedance matching unit M0 match impedances of the power amplifying unit AMP and the load RL. Herein, the description of the external impedance matching unit M0 is the same as that described in FIG. 1.

The internal impedance matching unit MI includes a first variable inductor unit illustrated as L1 connected between an output terminal of the power amplifying unit AMP and the first node N1 and having a variable inductance value, a second variable inductor unit illustrated as L2 connected between the first node N1 and the second node N2 and having a variable inductance value, a first variable capacitor unit illustrated as C1 connected between the first node N1 and a ground voltage terminal and having a variable capacitance value, and a second variable capacitor unit illustrated as C2 connected between the second node N2 and the ground voltage terminal and having a variable capacitance value.

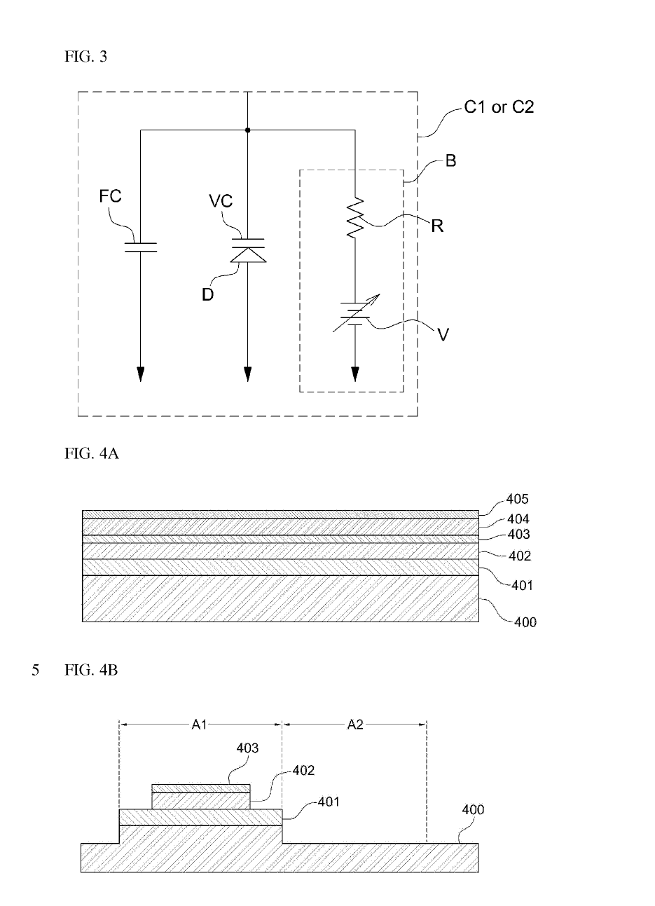

The first variable inductor unit L1 and the second variable inductor unit L2 include wirebonds. The inductance values of the first variable inductor unit L1 and the second variable inductor unit L2 are determined according to the number and the lengths of wires included in the wirebond. The first variable capacitor unit C1 and the second variable capacitor unit C2 will be described below in detail with reference to FIG. 3.

The internal impedance matching unit MI is configured by using a passive element capable of varying characteristic values (for example, the inductance value and the capacitance value) in order to easily control a matching characteristic with a multi-stage structure (meaning a structure including several nodes) for wideband matching. In FIG. 2, it is illustrated that the internal impedance matching unit MI includes two nodes N1 and N2. When the internal impedance matching unit MI has the multi-stage matching structure including several nodes, since the internal impedance matching unit MI may match the impedances while a quality factor Q value is maintained to be small, the wideband matching is enabled. Although the internal impedance matching unit MI having two nodes is illustrated in FIG. 2, the number of nodes that are included in the internal impedance matching unit MI and the number of passive elements may be varied depending on the design. Only when an element having a Q value which is as large as possible is used as the passive element, the loss of the signal may be reduced. As the number of the nodes increases, the wideband matching is enabled, but when the number of the nodes increases by one, each one of an inductor and a capacitor as the passive elements increases, and as a result, the number of the nodes may not be unlimitedly increased and the optimized number needs to be selected according to the design.

Frequency bands with which the impedances are matched are controlled by controlling the characteristic values (the impedance value or the capacitance value of the passive elements L1, L2, C1 and C2 included in the internal impedance matching unit MI to perform the impedance matching in a wider frequency range than a wideband matching circuit that operates in a fixed frequency band. Actual frequency bands with which the impedances are matched may be easily corrected by controlling a target frequency band and the characteristic values of the passive elements L1, L2, C1 and C2 due to a process characteristic and an additional package characteristic.

In FIG. 2, a case in which output impedances of the power amplifier are matched by using the internal impedance matching unit MI is illustrated, but the internal impedance matching unit MI may be used for input impedance matching or internode impedance matching according to design.

Since the power amplifier according to the exemplary embodiment of the present disclosure may perform wideband impedance matching while changing the frequency band unlike the related art, the power amplifier may be applied to various kinds of wireless communication terminals and systems. Accordingly, since one power amplifier operates in several frequency bands, a total area occupied by the power amplifier may be reduced by reducing the number of the power amplifiers included in the wireless communication terminal and system.

FIG. 3 is a configuration diagram of the variable capacitor units C1 and C2.

As illustrated in FIG. 3, the variable capacitor units C1 and C2 include a fixed capacitor illustrated as FC having a predetermined capacitance value, a diode illustrated as D which is connected to the fixed capacitor FC in parallel and in which a capacitance value depends on voltage applied to both terminals, and a biasing unit B for applying the voltage to the both terminals of the diode D.

The variable capacitor units C1 and C2 of FIG. 3 include both the fixed capacitor FC having the predetermined capacitance value and the diode D serving as the variable capacitor of which the capacitance value varies according to the voltage of the both terminals. As such, the reason that the variable capacitor units C1 and C2 include both the fixed capacitor FC and the diode D serving as the variable capacitor is that the variable capacitors C1 and C2 occupy a too large area when the variable capacitor units C1 and C2 are implemented by only the diode D because the capacitance value of the diode D is not significantly large. Therefore, the fixed capacitor FC having a large capacitance value is formed by using a dielectric together with the diode D to reduce the areas of the variable capacitor unit C1 and C2. For reference, a variable capacitor symbol VC drawn together with the diode D denotes that the diode D serves as the variable capacitor.

The capacitance value of the diode D is determined according to the magnitude of a bias voltage applied to the biasing unit B. The biasing unit B includes a resistor R and a voltage supplying unit V. The voltage of the voltage supplying unit V may be controlled. When a reverse bias is applied to the diode D by the biasing unit B, the capacitance value is generated in the diode D by a depleted region of the diode D. The capacitance value depends on the reverse bias voltage applied to both terminals of the diode D, and when the width of the depleted region is increased at a p-n junction of the diode D due to the increase in magnitude of the reverse bias, the capacitance value decreases, and when the width of the depleted region increases due to the decrease in magnitude of the reverse bias, the capacitance value increases.

Therefore, when the variable capacitor unit illustrated in FIG. 3 is used in the power amplifier, the capacitance value of the variable capacitor unit may be controlled as a bias value is controlled, thereby matching the power amplifier in a desired frequency band.

Referring back to FIGS. 2 and 3, the impedance matching circuit according to the exemplary embodiment of the present disclosure will be described.

The internal impedance matching unit MI included in the power amplifier illustrated in FIG. 2 corresponds to the impedance matching circuit according to the exemplary embodiment of the present disclosure. Accordingly, the impedance matching circuit includes a first variable inductor unit illustrated as L1 of which one end is connected to the first node N1 and an inductance value varies, a second inductor unit illustrated as L2 connected between the first node N1 and a second node illustrated as N2 and having a variable inductance value, a first variable capacitor unit illustrated as C1 of which one end is connected to the first node N1 and a capacitance value varies, and a second variable capacitor unit illustrated as C2 of which one end is connected to the second node N2 and a capacitance value varies, and the other end of the first variable capacitor unit C1 and the other end of the second variable capacitor unit C2 are connected to a ground voltage terminal to perform the impedance matching between a circuit connected to the other end of the first variable inductor unit L1 and a circuit connected to the second node L2.

Herein, the power amplifying unit AMP of FIG. 2 corresponds to the circuit connected to the other end of the first variable inductor unit L1, and the output impedance matching unit M0 corresponds to the second node N2. Hereinafter, the description of the internal impedance matching unit MI and the elements included in the internal impedance matching unit MI is the same as those described in FIGS. 2 and 3.

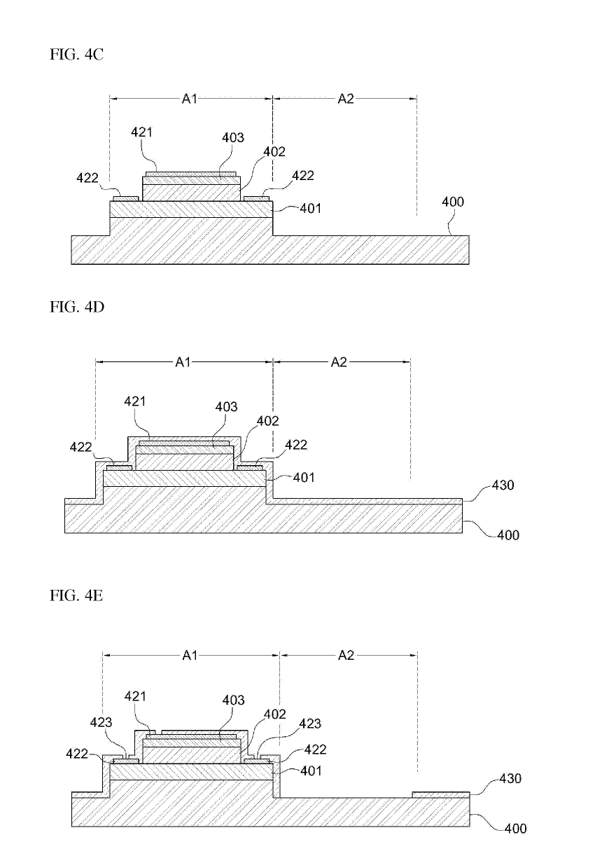

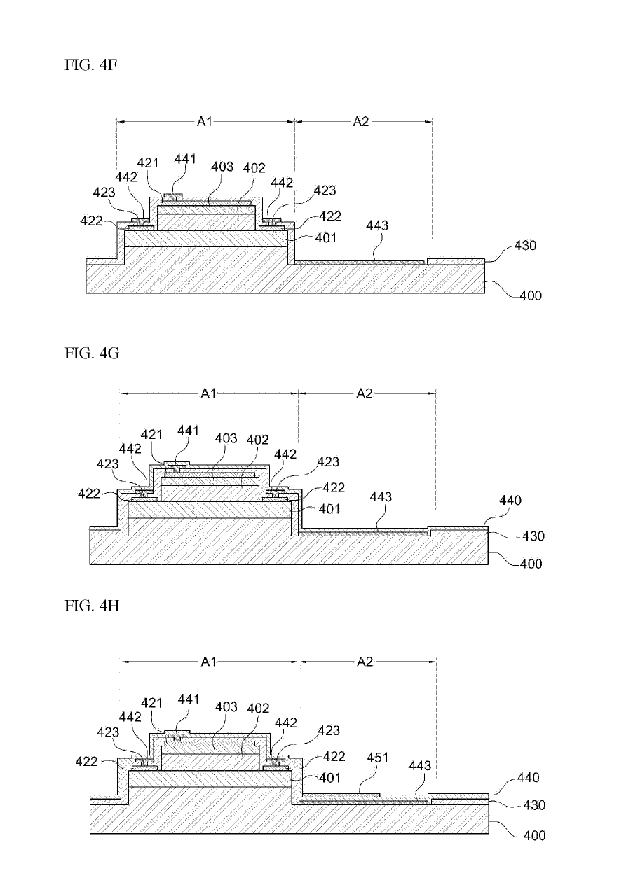

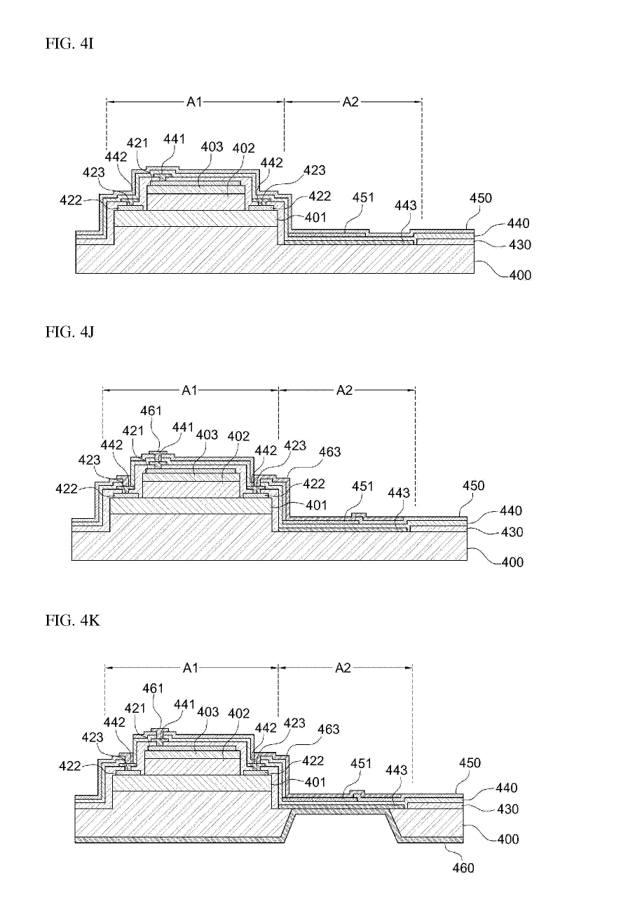

FIGS. 4A to 4K are diagrams for describing a manufacturing method for the variable capacitor (including the fixed capacitor FC and the diode D) included in the variable capacitor units C1 and C2 of FIG. 3. Herein, the variable capacitors C1 and C2 correspond to a compound semiconductor bipolar transistor.

The manufacturing method for the variable capacitor includes: forming a first element of which a capacitance value depends on a voltage applied to both terminals of a first area A1 on a substrate; forming a second element having a capacitance value fixed to a second area A2 on the substrate adjacent to the first area A1; and forming metallic wires 461 to 463 for connecting the first element and the second element and connecting the first element and the second element with the outside. Some and all of the respective steps of the exemplary embodiment of the present disclosure may be simultaneously performed.

The first element is a bipolar transistor and includes the diode as described below. The second element is a capacitor including a dielectric having a value of a fixed capacitance value. Hereinafter, the forming of the first element and the second element will be described.

As illustrated in FIG. 4A, compound semiconductor epitaxial layers are sequentially grown on a substrate 400 to form a preliminary sub-collector layer 401, a preliminary collector layer 402, a preliminary base layer 403, a preliminary emitter layer 404 and a preliminary emitter cap layer 405. An n-type dopant may be injected into the preliminary sub-collector layer 401 and the preliminary collector layer 402, and a high-density p-type dopant may be injected into the preliminary base layer 403. The n-type dopant may be injected into the preliminary emitter layer 404, and the high-density n-type dopant may be injected into the preliminary emitter cap layer 405.

As illustrated in FIG. 4B, in order to manufacture the variable capacitor, a photoresist pattern (not illustrated) is formed on the preliminary emitter cap layer 405, and the preliminary emitter cap layer 405 and the preliminary emitter layer 404 are etched by using the photoresist pattern as a mask to form the base layer 403. Next, the photoresist pattern (not illustrated) is formed on the base layer 403, and the preliminary base layer 403 and the preliminary collector layer 402 are etched by using the photoresist pattern as the mask to expose the preliminary sub-collector layer 401. The photoresist pattern (not illustrated) is formed and etching is performed up to a part of the substrate 400 to separate the element from the outside.

As illustrated in FIG. 4C, a collector electrode 422 contacting the sub-collector layer 401 and a base electrode 421 contacting the base layer 403 are formed. Herein, the collector electrode 422 and the base electrode 421 may be simultaneously formed. In detail, the collector electrode 422 and the base electrode 421 may be simultaneously formed by a lift-off method.

As illustrated in FIG. 4D, an insulating layer 430 covering the entire surface of the substrate 400 is formed. In more detail, the insulating layer 430 covers the collector electrode 423, the base electrode 422, the emitter electrode 421, the emitter cap layer 405, the emitter layer 404, the base layer 403, the collector layer 402, the sub-collector layer 401 and the substrate 400. The insulating layer 430 may be formed by a silicon nitride layer, a silicon oxide layer or a silicon oxide nitride layer.

As illustrated in FIG. 4E, a via for connecting a wire to the insulating layer 430 and a via for a lower electrode of the capacitor are formed.

As illustrated in FIG. 4F, a collector wire 442 contacting the collector electrode 422 and a base wire 441 contacting the base electrode 421 are formed on the insulating layer 430. A lower electrode 443 for forming the capacitor is formed. The wires 441 and 442 and the lower electrode 443 may be formed by the lift-off method.

As illustrated in FIG. 4G, a secondary insulating layer 440 covering the entire surface of the substrate 400 is formed. In more detail, the insulating layer 440 covers the collector electrode 422, the base electrode 421, the base layer 403, the collector layer 402, the sub-collector layer 401 and the substrate 400. Further, the insulating layer 440 covers the metallic wires 441 and 442 and the lower electrode 442 of the capacitor. The insulating layer 440 may be formed by the silicon nitride layer, the silicon oxide layer or the silicon oxide nitride layer. The insulating layer 440 is used for forming the fixed capacitor in the second area A2, and since the thickness of the insulating layer 440 influences the magnitude of the capacitance value of the fixed capacitor, the thickness of the insulating layer 440 needs to be accurately controlled in order to acquire an intended capacitance value.

As illustrated in FIG. 4H, after the insulating layer 440 is formed, a metal 451 used as an upper electrode of the capacitor is formed on the insulating layer 440. The upper electrode metal may be formed by the lift-off method.

The first element to be used as the variable capacitor is formed in the first area A1, and the second element to be used as the fixed capacitor is formed in the second area A2, through the processes illustrated in FIGS. 4A to 4H. For reference, the first element corresponds to the diode D of FIG. 3, and the second element corresponds to the fixed capacitor FC of FIG. 3. The diode D formed by using a first element (heterogeneous function element) epitaxial layer operates as the variable capacitor units C1 and C2 as described above. Since the base layer 403 of the epitaxial layer is a p-type, and the collector layer 402 and the sub-collector layer 401 are n-types, the diode D is formed and a separated wire for connecting the diode D to the voltage supplying unit V is provided in order to apply the bias voltage of the diode. The p-type of the diode is connected with an eternal ground voltage terminal.

Next, the forming of the metallic wires 460 and 463 for connecting the first element and the second element will be described.

Referring to FIG. 4I, a tertiary insulating layer 450 is formed. The tertiary insulating layer protects the elements and the passive elements. Further, a via for wire connection is formed.

As illustrated in FIG. 4J, after the via is formed, the capacitor metallic wire 463 for connecting the capacitor with the outside, the metallic wire 461 for connecting the p-type semiconductor of the diode with the ground voltage terminal and the metallic wire 462 for connecting the n-type semiconductor of the diode with the biasing unit B of FIG. 3 in order to control the bias voltage are formed. The metallic wire 462 may be formed by the lift-off method.

As illustrated in FIG. 4K, a rear metal 460 connected to the ground voltage terminal is deposited on a rear surface of the substrate through plating. In this case, a back-via process which is a rear-surface process may be used in a compound process in order to connect the lower electrode 443 of the capacitor to the ground voltage terminal.

The variable inductor units L1 and L2 of FIG. 2 correspond to metallic wires (not illustrated in FIG. 4J) to be connected to the metallic wire 463 of FIG. 4J. As described above, the variable inductor units L1 and L2 are formed by the wirebond, and the inductances of the variable inductor units L1 and L2 are determined according to the number and the lengths of the wires. Accordingly, when the length and the area of the metallic wire 463 are set to be large, the variable inductor units L1 and L2 may be effectively implemented. The upper electrode 451 of the fixed capacitor FC is connected with the variable inductor units L1 and L2 through the metallic wire 463, and the lower electrode 443 of the fixed capacitor FC is connected with the ground voltage terminal through the formed rear-surface metal 460.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An impedance matching circuit, comprising:
a first variable inductor unit of which one end is connected to the first node and an inductance value varies;
a second inductor unit connected between the first node and a second node and having a variable inductance value;
a first variable capacitor unit of which one end is connected to the first node and a capacitance value varies; and
a second variable capacitor unit of which one end is connected to the second node and a capacitance value varies,
wherein the other end of the first variable capacitor unit and the other end of the second variable capacitor unit are connected to a ground voltage terminal to perform the impedance matching between a circuit connected to the other end of the first variable inductor unit and a circuit connected to the second node.

2. The impedance matching circuit of claim 1, wherein:
the first inductor variable inductor unit and the second variable inductor unit include wirebonds, and
inductances of the first variable inductor unit and the second variable inductor unit are determined according to the number and the lengths of wires included in the wirebonds.

3. The impedance matching circuit of claim 1, wherein:
each of the first variable capacitor unit and the second variable capacitor unit includes
a fixed capacitor having a predetermined capacitance value;
a diode connected to the fixed capacitor in parallel and having a variable capacitance value according to a voltage applied to both terminals thereof; and
a biasing unit configured to apply the voltage to both terminals of the diode.

4. The impedance matching circuit of claim 3, wherein the biasing unit is configured to apply a reverse bias voltage to the diode.

5. The impedance matching circuit of claim 4, wherein when the magnitude of reverse bias voltage applied to both terminals of the diode increases, the capacitance value of the diode decreases.

6. A power amplifier circuit, comprising:
a power amplifying unit;
an output impedance matching unit of which one end is connected to an output node connected with a load to perform impedance matching; and
an internal impedance matching unit including a first node connected with an output terminal of the power amplifying unit and a second node connected with the other end of the output impedance matching unit, and performing the impedance matching,
wherein an impedance of the internal impedance matching unit varies.

7. The power amplifier circuit of claim 6, wherein:
the internal impedance matching unit includes
a first variable inductor unit connected between the output terminal of the power amplifying unit and the first node and having a variable inductance value;
a second inductor unit connected between the first node and a second node and having a variable inductance value;
a first variable capacitor unit connected between the first node and a ground voltage terminal and having a variable capacitance value; and
a second variable capacitor unit connected between the second node and the ground voltage terminal and having a variable capacitance value.

8. The power amplifier circuit of claim 7, wherein:
the first inductor variable inductor unit and the second variable inductor unit include wirebonds, and
inductances of the first variable inductor unit and the second variable inductor unit are determined according to the number and the lengths of wires included in the wirebonds.

9. The power amplifier circuit of claim 7, wherein:
each of the first variable capacitor unit and the second variable capacitor unit includes
a fixed capacitor having a predetermined capacitance value;
a diode connected to the fixed capacitor in parallel and having a variable capacitance value according to a voltage applied to both terminals thereof; and
a biasing unit configured to apply the voltage to both terminals of the diode.

10. The power amplifier circuit of claim 9, wherein the biasing unit is configured to apply the reverse bias voltage to the diode, and when the magnitude of the reverse bias voltage applied to both terminals of the diode increases, a capacitance value of the diode decreases.

11. A manufacturing method for a variable capacitor, comprising:
forming a first element of which a capacitance value depends on a voltage applied to both terminals of a first area on a substrate;
forming a second element having a capacitance value fixed to a second area on the substrate adjacent to the first area; and
forming metallic wires for connecting the first element and the second element and connecting the first element and the second element with the outside.

12. The method of claim 11, wherein the first element is a bipolar transistor.

13. The method of claim 12, wherein the bipolar transistor includes a diode.

14. The method of claim 11, wherein the second element is a capacitor including a dielectric.
